(19) United States
(12) Patent Application Publication
(10) Pub. No.: US 2014/0075262 A1
(43) Pub. Date: Mar. 13, 2014

(54) SEMICONDUCTOR INTEGRATED CIRCUIT

(71) Applicant: KABUSHIKI KAISHA TOSHIBA, Tokyo (JP)

(72) Inventor: Yoshiyuki KITASHO, Yokohama-shi (JP)

(21) Appl. No.: 13/841,977

(22) Filed: Mar. 15, 2013

(30) Foreign Application Priority Data
Sep. 10, 2012 (JP) 2012-198738

(51) Int. Cl. H03M 13/05

(52) U.S. Cl. CPC H03M 13/05
USPC 714/755

(57) ABSTRACT

According to one embodiment, a semiconductor integrated circuit includes an error correction circuit which executes an error correction processing of a first data read from a memory and outputs a second data in which the error correction processing is executed and a flag indicating a presence/absence of an error occurrence of the first data, a logic unit which executes a data processing of one of the first and second data, and a control unit which is configured to execute the error correction processing of the first data by using the error correction circuit, in parallel with executing the data processing of the first data by using the logic unit.

### CROSS-REFERENCE TO RELATED APPLICATIONS

This application is based upon and claims the benefit of priority from Japanese Patent Application No. 2012-198738, filed Sep. 10, 2012, the entire contents of which are incorporated herein by reference.

### FIELD

Embodiments described herein relate generally to a semiconductor integrated circuit.

### BACKGROUND

In a memory system including a memory such as a NAND flash memory and DRAM, an error may occur in a portion of data stored in the memory. As a countermeasure, for example, an error correction circuit that adds redundant bits to one unit of data during writing and makes an error correction based on the redundant bits during reading is mounted inside a controller that controls the memory.

Making error corrections of data stored in a memory is needed also to secure reliability of a memory system and, in recent years, the probability of an error occurrence in data stored in the memory is on the rise due to factors such as finer structures of memory cells. Thus, it is unavoidable to enhance an error correction function of the error correction circuit to correct such errors.

However, enhancing the error correction function means requiring a lot of time for error correction processing to correct errors. This apparently becomes a disadvantage of making, for example, the data processing time in the controller longer because the time to read data from the memory is made longer. Such a disadvantage is not desirable for recent electronic devices from which a high-speed operation is demanded and thus, the development of technology to reduce the influence thereof to a minimum is needed.

### BRIEF DESCRIPTION OF THE DRAWINGS

FIG. 1 is a diagram showing a semiconductor integrated circuit of a first embodiment;

FIG. 2 is a diagram showing a logic unit inside the circuit in FIG. 1;

FIG. 3 is a flow chart showing an operation of the circuit in FIG. 1;

FIG. 4 is a diagram showing an effect of reducing the data processing time;

FIG. 5 is a diagram showing a semiconductor integrated circuit of a second embodiment;

FIG. 6 is a diagram showing a logic unit inside the circuit in FIG. 5;

FIG. 7 is a flow chart showing the operation of the circuit in FIG. 5;

FIG. 8 is a diagram showing an effect of reducing the data processing time;

FIG. 9 is a diagram showing a semiconductor integrated circuit of a third embodiment;

FIG. 10 is a flow chart showing the operation of the circuit in FIG. 9;

FIG. 11 is a diagram showing a semiconductor integrated circuit of a fourth embodiment;

FIG. 12 is a flow chart showing the operation of the circuit in FIG. 11;

FIG. 13 is a diagram showing a semiconductor integrated circuit of a fifth embodiment;

FIG. 14 is a diagram showing a semiconductor integrated circuit of a sixth embodiment;

FIG. 15 is a diagram showing a semiconductor integrated circuit of a seventh embodiment;

FIG. 16 is a diagram showing a semiconductor integrated circuit of an eighth embodiment;

FIG. 17 is a flow chart showing the operation of the circuits in FIGS. 13 to 16;

FIG. 18 is a diagram showing a semiconductor integrated circuit of a ninth embodiment;

FIG. 19 is a diagram showing a semiconductor integrated circuit of a tenth embodiment;

FIG. 20 is a diagram showing a semiconductor integrated circuit of an eleventh embodiment;

FIG. 21 is a diagram showing a semiconductor integrated circuit of a twelfth embodiment;

FIG. 22 is a flow chart showing the operation of the circuits in FIGS. 18 to 21;

FIGS. 23 to 26 are diagrams showing a semiconductor integrated circuit of a thirteenth embodiment;

FIG. 27 is a flow chart showing the operation of the circuits in FIGS. 23 to 26;

FIGS. 28 to 31 are diagrams showing a semiconductor integrated circuit of a fourteenth embodiment;

FIG. 32 is a flow chart showing the operation of the circuits in FIGS. 28 to 31;

FIGS. 33 to 36 are diagrams showing a semiconductor integrated circuit of a fifteenth embodiment;

FIG. 37 is a diagram showing a semiconductor integrated circuit of a sixteenth embodiment;

FIG. 38 is a diagram showing a logic unit inside the circuit in FIG. 37;

FIG. 39 is a flow chart showing the operation of the circuit in FIG. 37;

FIG. 40 is a diagram showing a semiconductor integrated circuit of a seventeenth embodiment;

FIG. 41 is a flow chart showing the operation of the circuit in FIG. 40;

FIG. 42 is a diagram showing a memory system as an application example; and

FIG. 43 is a diagram showing an implementation example of the memory system.

### DETAILED DESCRIPTION

In general, according to one embodiment, a semiconductor integrated circuit comprises: an error correction circuit which executes an error correction processing of a first data read from a memory and outputs a second data in which the error correction processing is executed and a flag indicating a presence/absence of an error occurrence of the first data; a logic unit which executes a data processing of one of the first and second data; and a control unit which is configured to: execute the error correction processing of the first data by using the error correction circuit, in parallel with executing the data processing of the first data by using the logic unit, stop the data processing of the first data in the logic unit and execute the data processing of the second data by using the logic unit, when the flag indicates the error occurrence, and continues the data processing of the first data in the logic unit when the flag indicates no error occurrence.

The embodiments will be described below with reference to the drawings.

### (Overview)

When an error correction circuit is adopted for a memory system including a memory such as a NAND flash memory and DRAM, the error correction function desirably has optimal capabilities according to the frequency of error occurrence of data stored in the memory. However, the frequency of error occurrence changes depending on the period of using the memory system (number of times of writing/reading data to/from the memory) and the environment in which the memory system is installed.

That the error correction function adopted for the memory system is fixed even if the frequency of error occurrence of data stored in the memory changes is a disadvantage to make the most of performance of the memory system. That is, in a memory system in which the error correction function is fixed, the error correction function in an error correction circuit operates regardless of the presence/absence of an error occurrence and the frequency of error occurrence.

Thus, in the embodiments that follow, a memory system capable of selectively executing data processing by a logic unit on one of data before error corrections and data after error corrections according to the presence/absence of an error occurrence is first proposed.

That is, when no error occurs in data stored in the memory, data on which no error correction processing is executed, that is, data directly read from the memory is used for data processing by the logic unit and when an error occurs in data stored in the memory, data on which error correction processing is executed is used for data processing by the logic unit.

Accordingly, an increase in the data processing time due to the error correction processing can be reduced to a minimum, leading to improved performance of the memory system.

Secondly, a memory system capable of selectively executing data processing by a logic unit on one of data after error corrections by an error correction circuit of high-speed operation priority (high-speed version) and data after error corrections by an error correction circuit of error correction operation priority (enhanced version) according to the frequency of error occurrence is proposed.

That is, when the frequency of error occurrence of data stored in the memory is equal to a predetermined value or less, data after error corrections by the error correction circuit of high-speed operation priority is used for data processing by the logic unit and when the frequency of error occurrence of data stored in the memory exceeds a predetermined value, data after error corrections by the error correction circuit of error correction operation priority is used for data processing by the logic unit.

Accordingly, an increase in the data processing time due to the error correction processing can be reduced to a minimum, leading to improved performance of the memory system.

Further, thirdly, a memory system capable of selectively executing data processing by a logic unit on one of data after error corrections by an error correction circuit of high-speed operation priority and data after error corrections by an error correction circuit of error correction operation priority according to the type of memory (such as the NAND flash memory, DRAM, binary memory, and multivalued memory) is proposed.

That is, when data is written/read to/from a memory having a low frequency of error occurrence, data after error corrections by the error correction circuit of high-speed operation priority is used for data processing by the logic unit and when data is written/read to/from a memory having a high frequency of error occurrence, data after error corrections by the error correction circuit of error correction operation priority is used for data processing by the logic unit.

Accordingly, an increase in the data processing time due to the error correction processing can be reduced to a minimum, leading to improved performance of the memory system.

### (Embodiments)

Technology for advance processing of data before error corrections (FIGS. 1 to 12)

The present technology relates to a memory system capable of selectively executing data processing by a logic unit on one of data before error corrections and data after error corrections according to the presence/absence of an error occurrence.

The present technology is characterized in that data processing is executed on data (data before error corrections) by a logic unit immediately the data is read from a memory. That is, advance processing is executed on data before error corrections. Error correction processing is executed on the data from the memory in parallel therewith and if an error occurrence is detected, the advance processing of data before error corrections is stopped and data processing by the logic unit is executed on data after error corrections again. If no error occurrence is detected, the advance processing of data before error corrections is continued.

In this case, if no error occurs in data from the memory, data processing can be executed on data before error corrections regardless of the error correction processing time and thus, for example, the data processing time in a controller can significantly be reduced. If an error occurs in data from the memory, data processing is executed on data after error corrections and thus, no system problem will arise.

The first to fourth embodiments of the present technology will be described below.

FIG. 1 shows a semiconductor integrated circuit according to the first embodiment.

Memory 11 is, for example, a nonvolatile memory such as a NAND flash memory or a volatile memory such as a DRAM. Error correction circuit 13 executes error correction processing of first data DATA-a read from memory 11 and outputs second data DATA-b on which the error correction processing has been executed and flag F indicating the presence/absence of an error occurrence in first data DATA-a.

Logic unit 12 executes data processing on one of first and second data DATA-a, DATA-b.

Control unit 14 controls the operation so that logic unit 12 uses first data DATA-a for data processing when no error occurs in first data DATA-a and second data DATA-b for data processing when an error occurs in first data DATA-a.

Control unit 14 determines the presence/absence of an error occurrence in first data DATA-a based on, for example, flag F output by error correction circuit 13 and outputs selection signal Cφ to select one of first and second data DATA-a, DATA-b and reset signal RS to decide whether to stop processing (advance processing) of first data DATA-a.

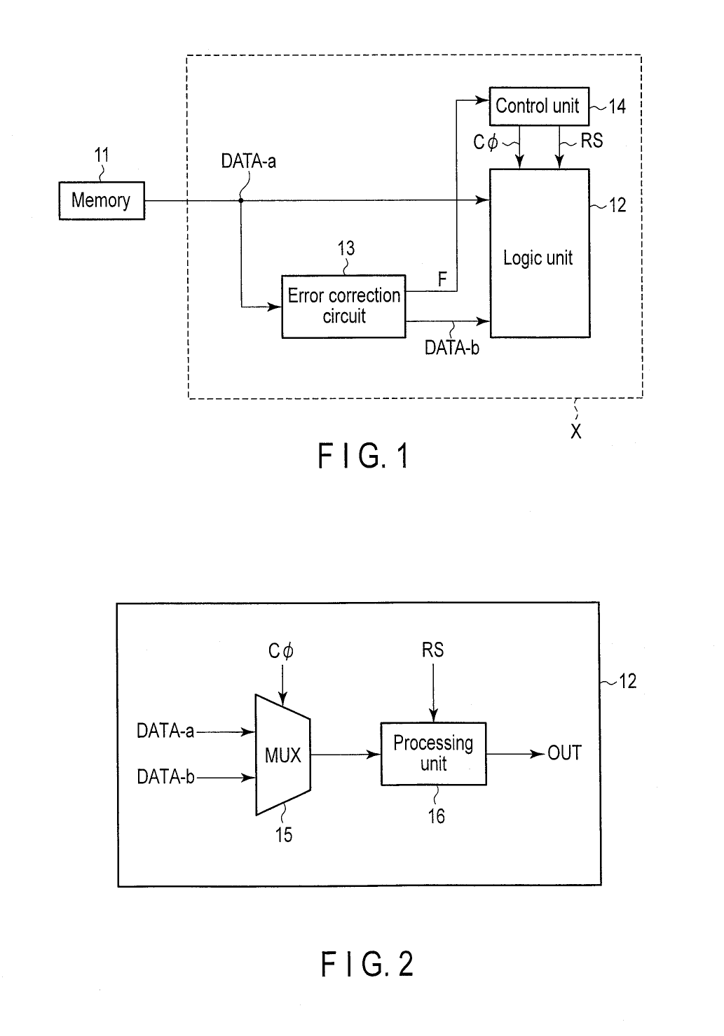

FIG. 2 shows a logic unit in FIG. 1.

Logic unit 12 includes multiplexer 15 that selects one of first and second data DATA-a, DATA-b based on selection signal Cφ and processing unit 16 that executes data processing on one of first and second data DATA-a, DATA-b.

Processing unit 16 is reset by reset signal RS. For example, data processing (advance processing) on first data DATA-a by processing unit 16 is stopped when reset signal RS becomes active.

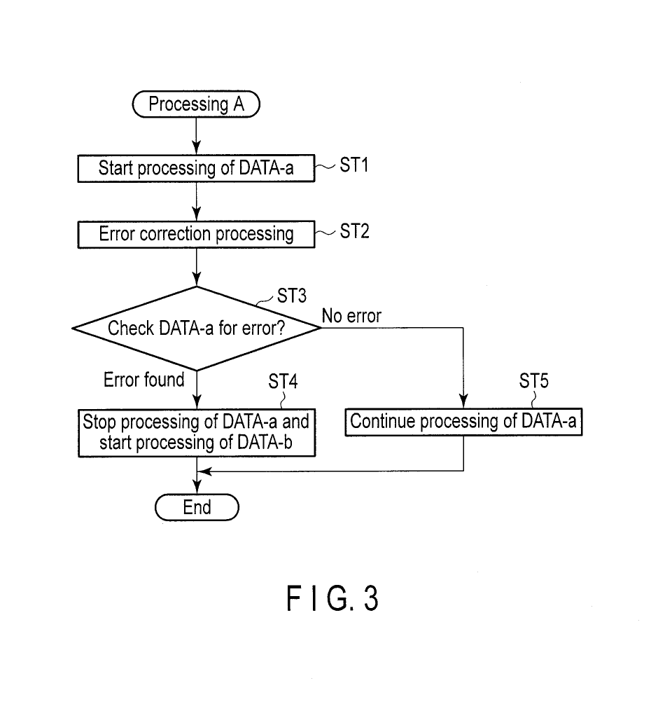

FIG. 3 shows an operation of a circuit in FIG. 1.

The operation is controlled by control unit 14 in FIG. 1.

First, when first data DATA-a is read from memory 11, logic unit 12 starts data processing (advance processing) on first data DATA-a (step ST1).

In parallel with the advance processing, error correction circuit 13 executes error correction processing on first data DATA-a (step ST2).

These two steps ST1, ST2 may be interchanged or integrated into one step.

Next, first data DATA-a is checked for an error (step ST3).

The check is done based on, for example, flag F output by error correction circuit 13. If flag F indicates an error occurrence, logic unit 12 stops data processing of first data DATA-a (resets processing unit 16) and instead, starts data processing of second data DATA-b (step ST4).

If flag F indicates no error occurrence, logic unit 12 continues data processing of first data DATA-a (step ST5).

According to the first embodiment, as described above, an increase in the data processing time due to the error correction processing can be reduced to a minimum, leading to improved performance of the memory system.

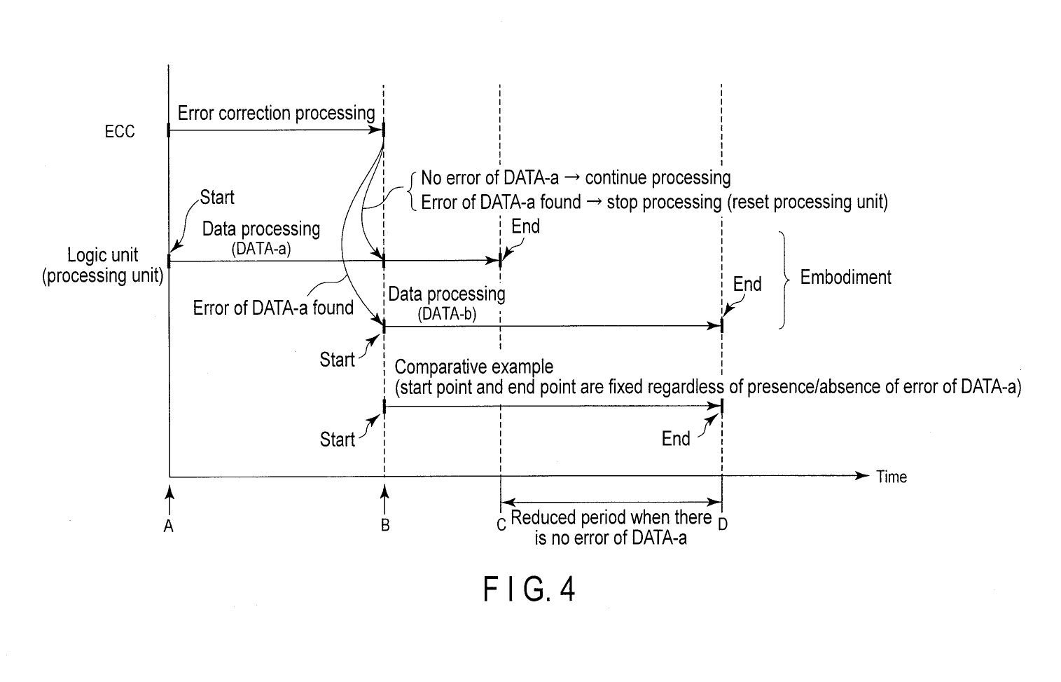

FIG. 4 shows an effect of reducing the data processing time.

In the present embodiment, when first data DATA-a is read from memory 11, data processing of first data DATA-a is immediately started (point A).

In parallel therewith, error correction processing of first data DATA-a is executed.

Then, if an error occurrence is detected, advance processing of first data DATA-a is stopped and data processing of second data DATA-b after error corrections is restarted. If no error occurrence is detected, the advance processing of first data DATA-a before error corrections is continued (point B).

In this case, if no error occurs in first data DATA-a, data processing can be executed on first data DATA-a regardless of the error correction processing time and thus, for example, the period between point C and point D can be reduced, resulting in a significant reduction of the data processing time in the controller.

In a comparative example, by contrast, data processing of second data DATA-b on which error correction processing has been executed is always executed regardless of the presence/absence of an error occurrence and thus, for example, even if no error occurs, data processing by the logic unit needs to be started after the error correction processing time (period between point A and point B).

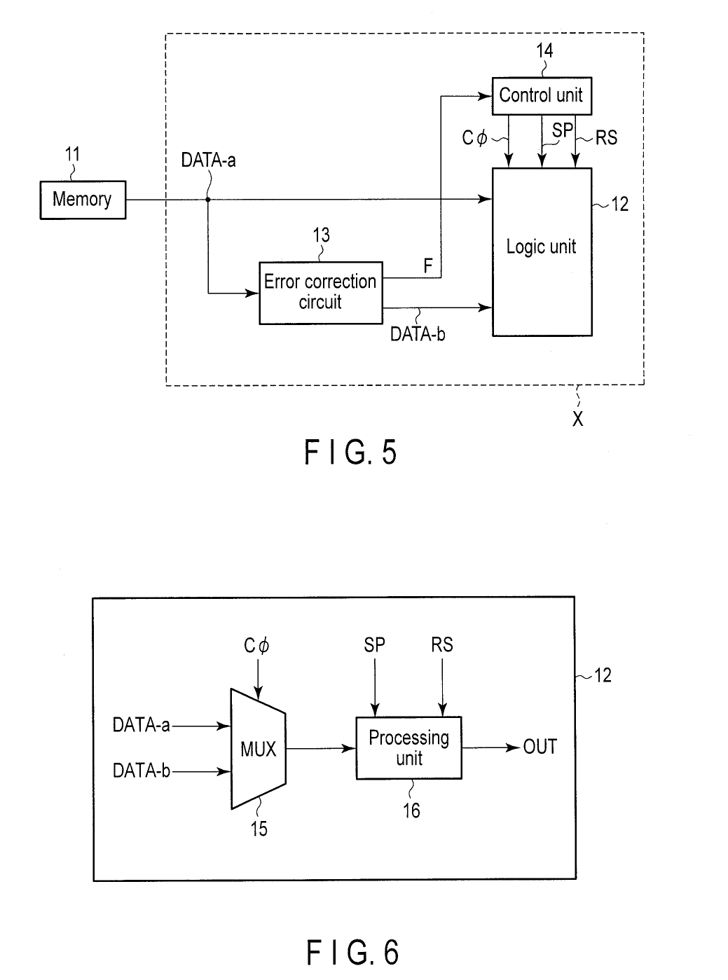

FIG. 5 shows a semiconductor integrated circuit according to the second embodiment.

The second embodiment is a modification of the first embodiment. When compared with the first embodiment, the second embodiment is characterized by the configuration of control unit 14. The configuration excluding control unit 14 is the same as shown in FIG. 1 (first embodiment) and thus, the same reference numerals are attached to the same elements as those in FIG. 1 to omit a detailed description thereof.

In the present embodiment, control unit 14 determines the presence/absence of an error occurrence in, for example, first data DATA-a based on flag F output by error correction circuit 13. Control unit 14 outputs selection signal Cφ to select one of first and second data DATA-a, DATA-b, pause signal SP to interrupt processing (advance processing) of first data DATA-a at a fixed point, and reset signal RS to decide whether to stop processing (advance processing) of first data DATA-a.

FIG. 6 shows a logic unit in FIG. 5.

Logic unit 12 includes multiplexer 15 that selects one of first and second data DATA-a, DATA-b based on selection signal Cφ and processing unit 16 that executes data processing on one of first and second data DATA-a, DATA-b.

Data processing by processing unit 16 is interrupted by pause signal SP. For example, data processing of first data DATA-a is paused when pause signal SP becomes active and then, when pause signal SP becomes non-active, data processing of first data DATA-a is restarted.

Processing unit 16 is reset by reset signal RS. For example, data processing of first data DATA-a by processing unit 16 is stopped when reset signal RS becomes active.

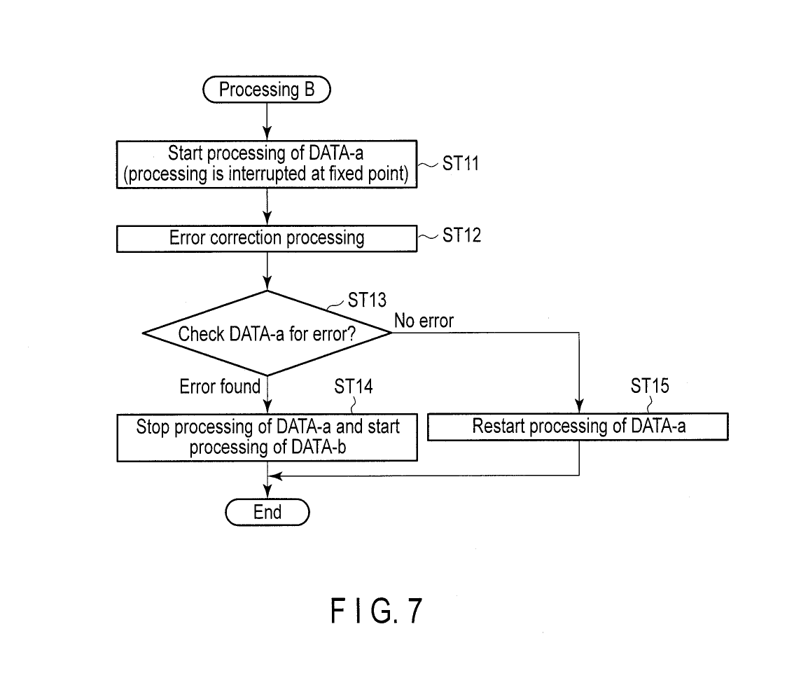

FIG. 7 shows the operation of the circuit in FIG. 5.

The operation is controlled by control unit 14 in FIG. 5.

First, when first data DATA-a is read from memory 11, logic unit 12 starts data processing (advance processing) on first data DATA-a. The data processing is interrupted at a fixed point (step ST11).

In parallel with the advance processing, error correction circuit 13 executes error correction processing on first data DATA-a (step ST12).

These two steps ST11, ST12 may be interchanged or integrated into one step.

Next, first data DATA-a is checked for an error (step ST13).

The check is done based on, for example, flag F output by error correction circuit 13. If flag F indicates an error occurrence, logic unit 12 stops data processing of first data DATA-a (resets processing unit 16) and instead, starts data processing of second data DATA-b (step ST14).

If flag F indicates no error occurrence, logic unit 12 restarts data processing of first data DATA-a (step ST15).

Also in the second embodiment, as described above, an increase in the data processing time due to the error correction processing can be reduced to a minimum, leading to improved performance of the memory system.

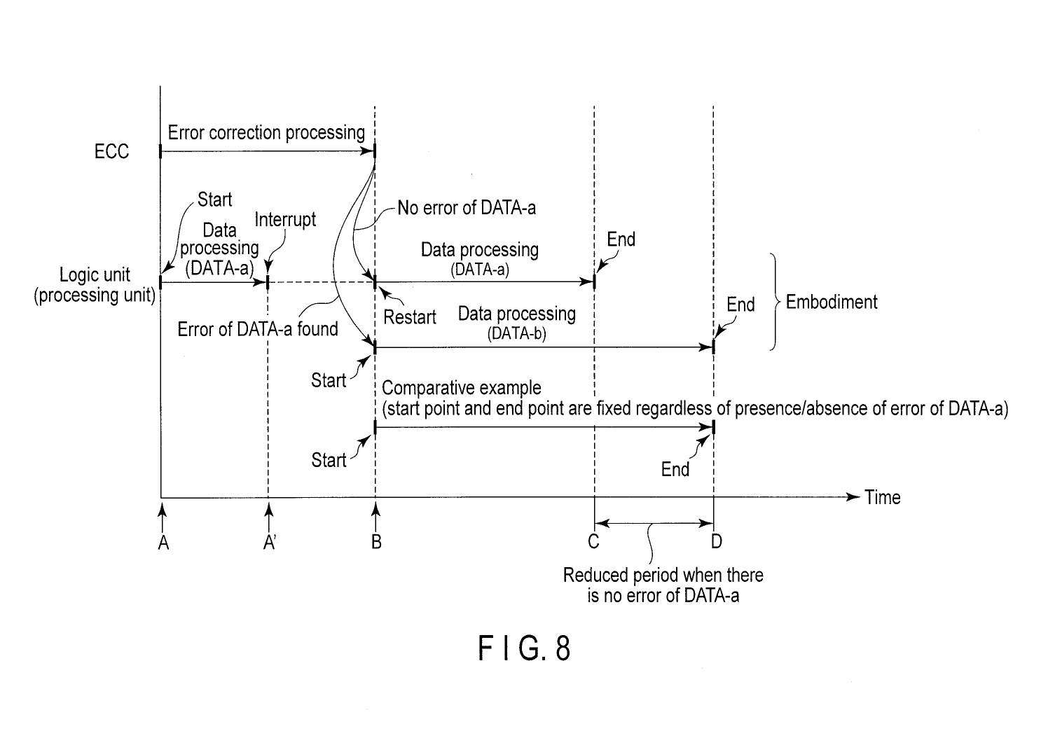

FIG. 8 shows an effect of reducing the data processing time.

In the present embodiment, when first data DATA-a is read from memory 11, data processing of first data DATA-a is immediately started (point A).

The data processing of first data DATA-a is interrupted at a fixed point (point A′).

In parallel therewith, error correction processing of first data DATA-a is executed.

Then, if an error occurrence is detected, advance processing of first data DATA-a is stopped and data processing of second data DATA-b after error corrections is restarted. If no error occurrence is detected, the advance processing of first data DATA-a before error corrections is restarted (point B).

In this case, if no error occurs in first data DATA-a, data processing can be executed on first data DATA-a regardless of the error correction processing time and thus, for example, the period between point C and point D can be reduced, resulting in a significant reduction of the data processing time in the controller.

In a comparative example, by contrast, data processing of second data DATA-b on which error correction processing has been executed is always executed regardless of the presence/absence of an error occurrence and thus, for example, even if no error occurs, data processing by the logic unit needs to be started after the error correction processing time (period between point A and point B).

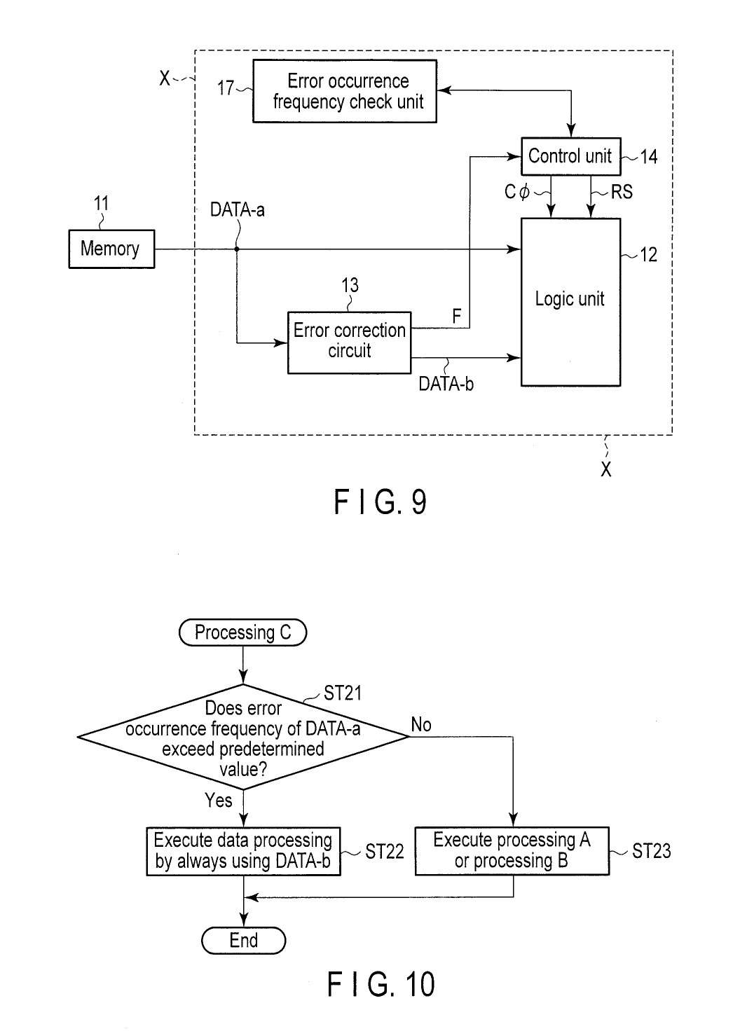

FIG. 9 shows a semiconductor integrated circuit according to the third embodiment.

The third embodiment is a modification of the first embodiment. When compared with the first embodiment, the third embodiment is characterized in that error occurrence frequency check unit 17 is further included. The configuration excluding error occurrence frequency check unit 17 is the same as shown in FIG. 1 (first embodiment) and thus, the same reference numerals are attached to the same elements as those in FIG. 1 to omit a detailed description thereof.

In the present embodiment, error occurrence frequency check unit 17 accumulates and stores the frequency of error occurrence of, for example, first data DATA-a. The frequency of error occurrence is accumulated and stored in error occurrence frequency check unit 17 based on, for example, flag F. In this case, flag F contains 1 bit indicating the presence/absence of an error occurrence and bits indicating the frequency of error occurrence (number of error bits).

Then, when the frequency of error occurrence of memory 11 exceeds a predetermined value (permitted value of the number of error bits), control unit 14 causes logic unit 12 to execute data processing on second data DATA-b. For example, control unit 14 continues to output selection signal Cφ to always select second data DATA-b.

In the present embodiment, the configuration inside logic unit 12 is the same as shown in FIG. 2 (first embodiment) and thus, the description here is omitted.

Further, the present embodiment has been described as a modification of the first embodiment, but error occurrence frequency check unit 17 in the present embodiment can also be provided in the second embodiment.

FIG. 10 shows the operation of the circuit in FIG. 9.

The operation is controlled by control unit 14 in FIG. 9.

First, processing according to the presence/absence of an error in first data DATA-a, that is, processing A (FIG. 3) in the first embodiment or processing B (FIG. 7) in the second embodiment is executed.

Then, whether the frequency of error occurrence of first data DATA-a exceeds the predetermined value is determined (step ST21).

Next, if the frequency of error occurrence exceeds the predetermined value, data processing is always executed on second data DATA-b (step ST22). Thus, if such a high fixed frequency of error occurrence is reached, the probability of discarding first data DATA-a processed in advance increases. If the probability of discarding is high from the beginning, extra data processing can be saved and by extension, an increase in power consumption of the circuit can be reduced by executing data processing after waiting for second data DATA-b without advancing data processing.

If the frequency of error occurrence does not exceed the predetermined value, processing A (FIG. 3) in the first embodiment or processing B (FIG. 7) in the second embodiment is continued (step ST23).

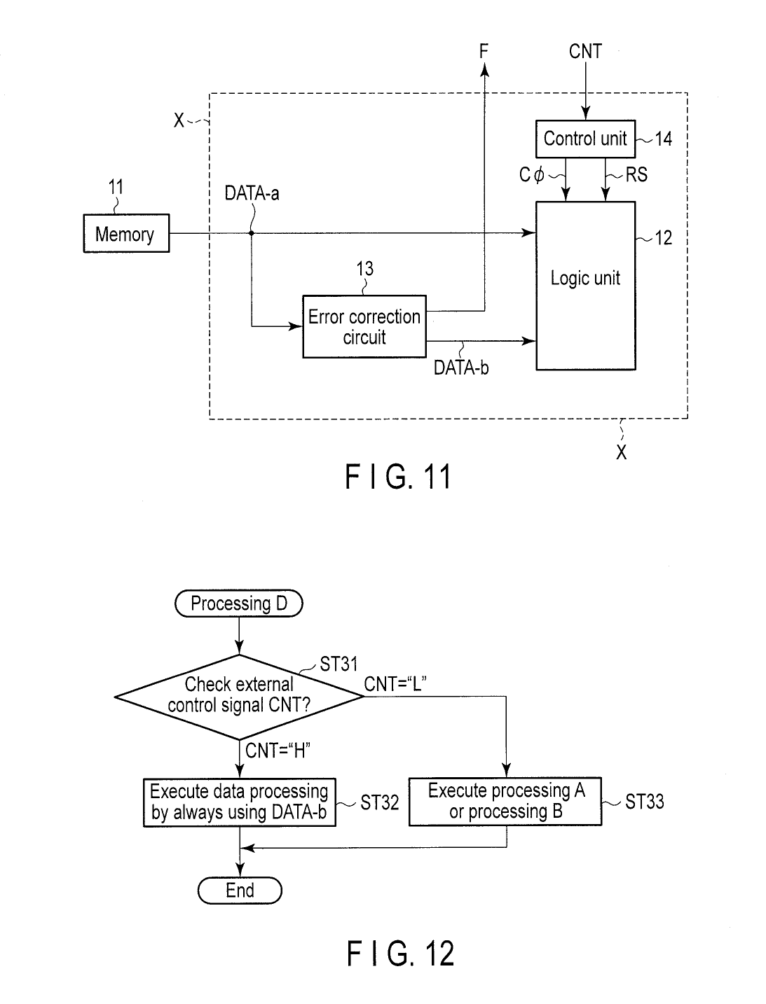

FIG. 11 shows a semiconductor integrated circuit according to the fourth embodiment.

The fourth embodiment is a modification of the first embodiment. When compared with the first embodiment, the fourth embodiment is characterized in that data (one of first and second data DATA-a, DATA-b) used for data processing by logic unit 12 can be selected based on external control signal CNT. The other configuration is the same as shown in FIG. 1 (first embodiment) and thus, the same reference numerals are attached to the same elements as those in FIG. 1 to omit a detailed description thereof.

In the present embodiment, when external control signal CNT indicates a predetermined value, logic unit 12 is caused to execute data processing on second data DATA-b. External control signal CNT decides its value based on, for example, flag F from error correction circuit 13. In this case, flag F contains 1 bit indicating the presence/absence of an error occurrence and bits indicating the frequency of error occurrence (number of error bits).

Then, for example, when the frequency of error occurrence exceeds the predetermined value (permitted value of the number of error bits), external control signal CNT indicates a predetermined value to select second data DATA-b. That is, control unit 14 continues to output selection signal Cφ to always select second data DATA-b.

External control signal CNT is generated by a separate host (CPU) from a controller chip X. That is, the host generates external control signal CNT based on, for example, software.

In the present embodiment, the configuration inside logic unit 12 is the same as shown in FIG. 2 (first embodiment) and thus, the description here is omitted. The present embodiment has been described as a modification of the first embodiment, but the present embodiment can also be applied to the second embodiment.

FIG. 12 shows the operation of the circuit in FIG. 11.

The operation is controlled by control unit 14 in FIG. 11.

First, processing according to the presence/absence of an error in first data DATA-a, that is, processing A (FIG. 3) in the first embodiment or processing B (FIG. 7) in the second embodiment is executed.

Then, external control signal CNT is checked (step ST31).

Next, if external control signal CNT indicates a predetermined value (for example, “H”), data processing is executed on second data DATA-b (step ST32). If external control signal CNT indicates a value (for example, “L”) other than the predetermined value, processing A (FIG. 3) in the first embodiment or processing B (FIG. 7) in the second embodiment is executed (step ST33).

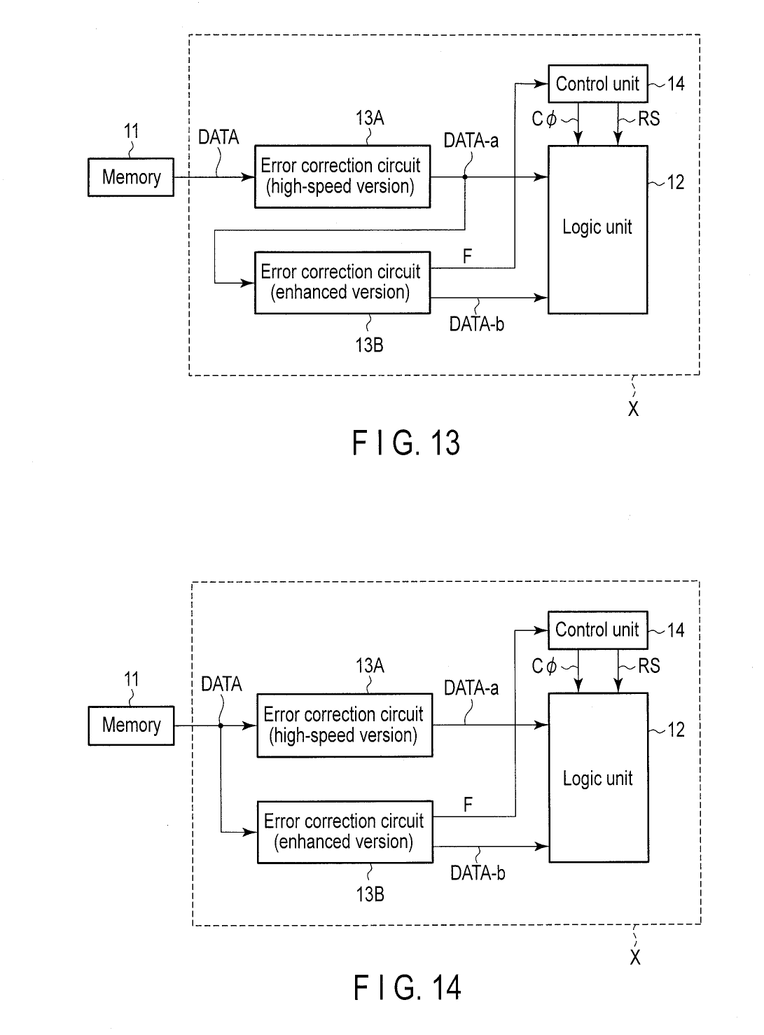

Technology for advance processing of data after simple error corrections (FIGS. 13 to 32).

The present technology relates to a memory system capable of selectively executing data processing by a logic unit on one of data after error corrections by an error correction circuit of high-speed operation priority (high-speed version) and data after error corrections by an error correction circuit of error correction operation priority (enhanced version) according to the frequency of error occurrence.

The present technology is characterized in that when data is read from a memory, simple error correction processing is first executed and data processing is executed on data after simple error corrections. That is, data after simple error corrections is processed in advance. Enhanced error correction processing is executed on the data from the memory in parallel therewith and if an error occurrence is detected, the advance processing of data after simple error corrections is stopped and data processing is executed on data after enhanced error corrections again. If no error occurrence is detected, the advance processing of data after simple error corrections is continued.

In this case, if no error occurs in data on which enhanced error correction processing should be executed, data processing can be executed on data after simple error corrections regardless of the error correction processing time by the error correction circuit (enhanced version) and thus, for example, the data processing time in a controller can significantly be reduced. If an error occurs in data on which enhanced error correction processing should be executed, data processing is executed on data after enhanced error corrections and thus, no system problem will arise.

The speed of simple error corrections by the error correction circuit (high-speed version) is faster than the speed of enhanced error corrections by the error correction circuit (enhanced version). Moreover, the error correction function by the error correction circuit (enhanced version) is more enhanced than the error correction function by the error correction circuit (high-speed version).

The fifth to twentieth embodiments of the present technology will be described below.

FIG. 13 shows a semiconductor integrated circuit according to the fifth embodiment.

Memory 11 is, for example, a nonvolatile memory such as a NAND flash memory or a volatile memory such as a DRAM.

Error correction circuit (high-speed version) 13A executes simple error correction processing of first data DATA read from memory 11 and outputs second data DATA-a on which simple error correction processing has been executed. Error correction circuit (enhanced version) 13B executes enhanced error correction processing of second data DATA-a and outputs third data DATA-b on which enhanced error correction processing has been executed and flag F indicating the presence/absence of an error occurrence in second data DATA-a.

Logic unit 12 executes data processing on one of second and third data DATA-a, DATA-b.

Control unit 14 controls the operation so that logic unit 12 uses second data DATA-a for data processing when no error occurs in second data DATA-a and third data DATA-b for data processing when an error occurs in second data DATA-a.

Control unit 14 determines the presence/absence of an error occurrence in second data DATA-a based on, for example, flag F output by error correction circuit (enhanced version) 13B and outputs selection signal Cφ to select one of second and third data DATA-a, DATA-b and reset signal RS to decide whether to stop processing (advance processing) of second data DATA-a.

The configuration of logic unit 12 in FIG. 13 is the same, for example, as shown in FIG. 2 (first embodiment) and thus, the description here is omitted.

FIG. 14 shows a semiconductor integrated circuit according to the sixth embodiment.

The sixth embodiment is a modification of the fifth embodiment. When compared with the fifth embodiment, the sixth embodiment is characterized by data input into error correction circuit (enhanced version) 13B. The other configuration is the same as shown in FIG. 13 (fifth embodiment) and thus, the same reference numerals are attached to the same elements as those in FIG. 13 to omit a detailed description thereof.

In the present embodiment, first data DATA read from memory 11 is input into error correction circuit (enhanced version) 13B.

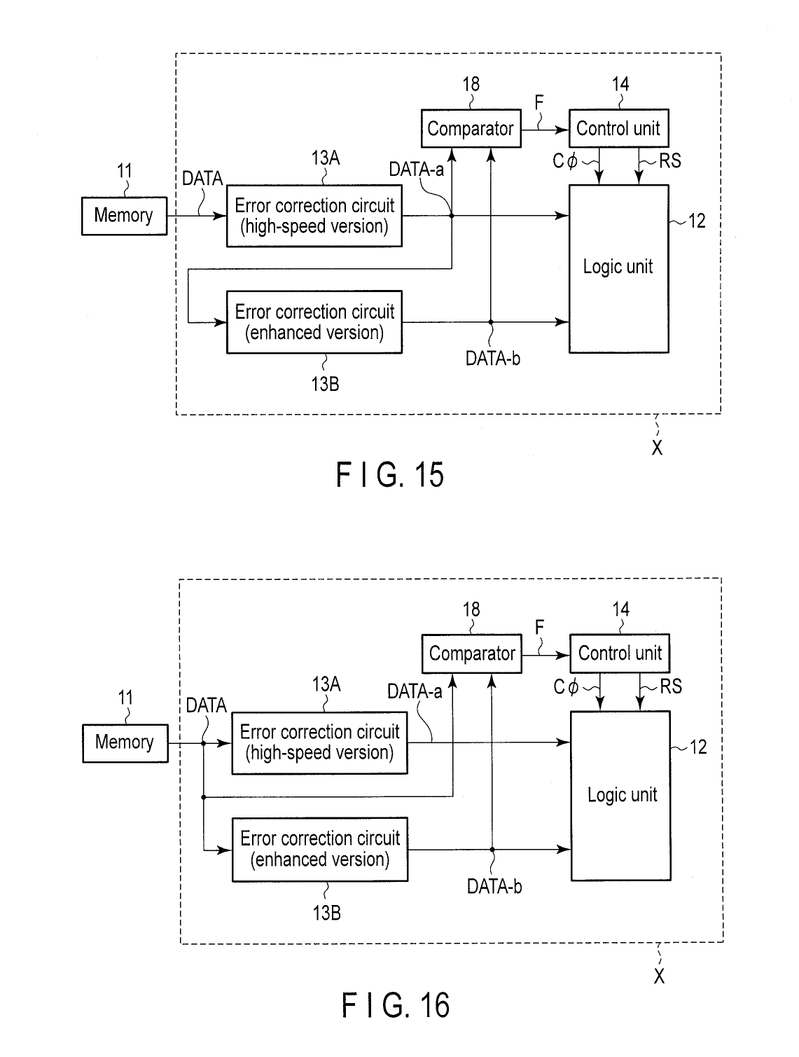

FIG. 15 shows a semiconductor integrated circuit according to the seventh embodiment.

The seventh embodiment is also a modification of the fifth embodiment. When compared with the fifth embodiment, the seventh embodiment is characterized in that flag F indicating the presence/absence of an error occurrence in second data DATA-a is generated by comparator 18 that compares second and third data DATA-a, DATA-b. The configuration excluding comparator 18 is the same as shown in FIG. 13 (fifth embodiment) and thus, the same reference numerals are attached to the same elements as those in FIG. 13 to omit a detailed description thereof.

In the present embodiment, second and third data DATA-a, DATA-b are input into comparator 18. Then, comparator 18 outputs flag F indicating the presence/absence of an error occurrence of second data DATA-a by comparing second and third data DATA-a, DATA-b.

FIG. 16 shows a semiconductor integrated circuit according to the eighth embodiment.

The eighth embodiment is a modification of the sixth embodiment. When compared with the sixth embodiment, the eighth embodiment is characterized in that flag F indicating the presence/absence of an error occurrence in first data DATA is generated by comparator 18 that compares first and third data DATA, DATA-b. The configuration excluding comparator 18 is the same as shown in FIG. 14 (sixth embodiment) and thus, the same reference numerals are attached to the same elements as those in FIG. 14 to omit a detailed description thereof.

In the present embodiment, first and third data DATA, DATA-b are input into comparator 18. Then, comparator 18 outputs flag F indicating the presence/absence of an error occurrence of first data DATA by comparing first and third data DATA, DATA-b.

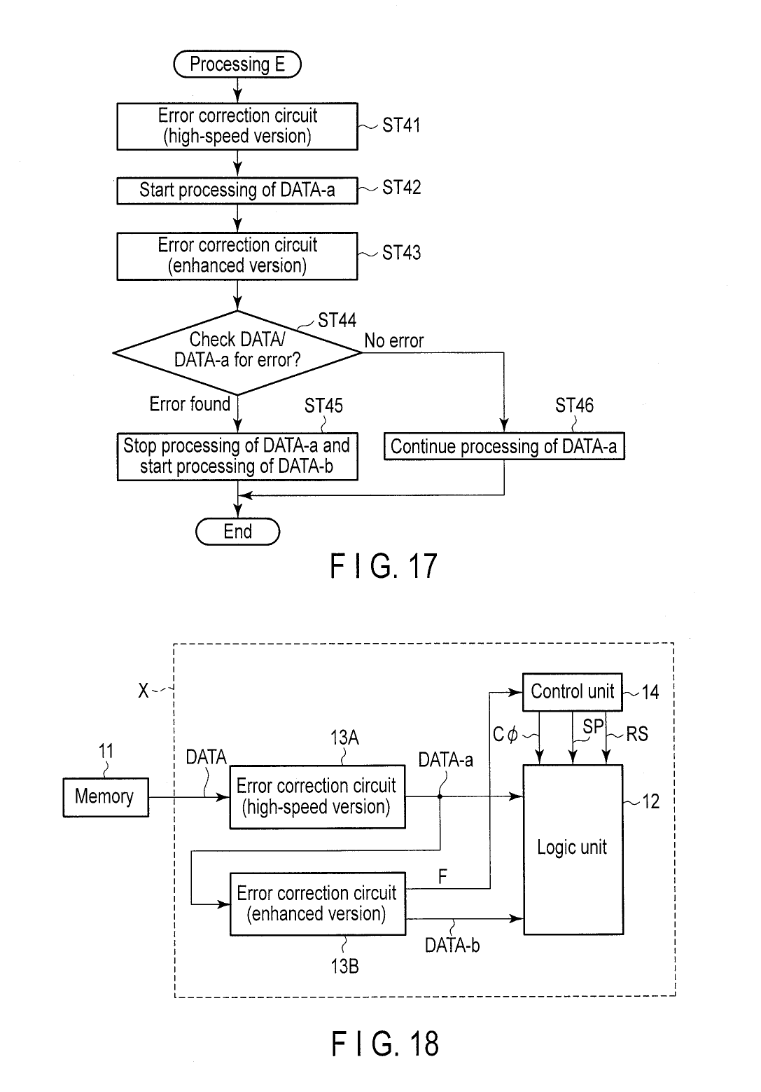

FIG. 17 shows the operation of the circuits in FIGS. 13 to 16.

The operation is controlled by control unit 14 in FIGS. 13 to 16.

First, when first data DATA is read from memory 11, error correction circuit (high-speed version) 13A executes simple error correction processing of first data DATA (step ST41).

Next, logic unit 12 starts data processing (advance processing) of second data DATA-a on which simple error correction processing has been executed (step ST42).

In parallel with the advance processing, error correction circuit (enhanced version) 13B executes enhanced error correction processing of first data DATA (corresponding to FIGS. 14 and 16) or second data DATA-a (corresponding to FIGS. 13 and 15) (step ST43).

These two steps ST42, ST43 may be interchanged or integrated into one step.

Next, first DATA (corresponding to FIGS. 14 and 16) or second data DATA-a (corresponding to FIGS. 13 and 15) is checked for an error (step ST44).

The check is done based on, for example, flag F output by error correction circuit (enhanced version) 13B or comparator 18. If flag F indicates an error occurrence, logic unit 12 stops data processing of second data DATA-a (resets processing unit 16) and instead, starts data processing of third data DATA-b (step ST45).

If flag F indicates no error occurrence, logic unit 12 continues data processing of second data DATA-a (step ST46).

According to the fifth to eighth embodiments, as described above, an increase in the data processing time due to the error correction processing can be reduced to a minimum, leading to improved performance of the memory system. Also in the fifth to eighth embodiments, an effect of reducing the data processing time shown in FIG. 4 can be obtained.

FIG. 18 shows a semiconductor integrated circuit according to the ninth embodiment.

The ninth embodiment is a modification of the fifth embodiment. When compared with the fifth embodiment, the ninth embodiment is characterized by the configuration of control unit 14. The configuration excluding control unit 14 is the same as shown in FIG. 13 (fifth embodiment) and thus, the same reference numerals are attached to the same elements as those in FIG. 13 to omit a detailed description thereof.

In the present embodiment, control unit 14 determines the presence/absence of an error occurrence in, for example, second data DATA-a based on flag F output by error correction circuit (enhanced version) 13B. Control unit 14 outputs selection signal Cφ to select one of second and third data DATA-a, DATA-b, pause signal SP to interrupt processing (advance processing) of second data DATA-a at a fixed point, and reset signal RS to decide whether to stop processing (advance processing) of second data DATA-a.

The configuration of logic unit 12 in FIG. 18 is the same, for example, as shown in FIG. 6 (second embodiment) and thus, the description here is omitted.

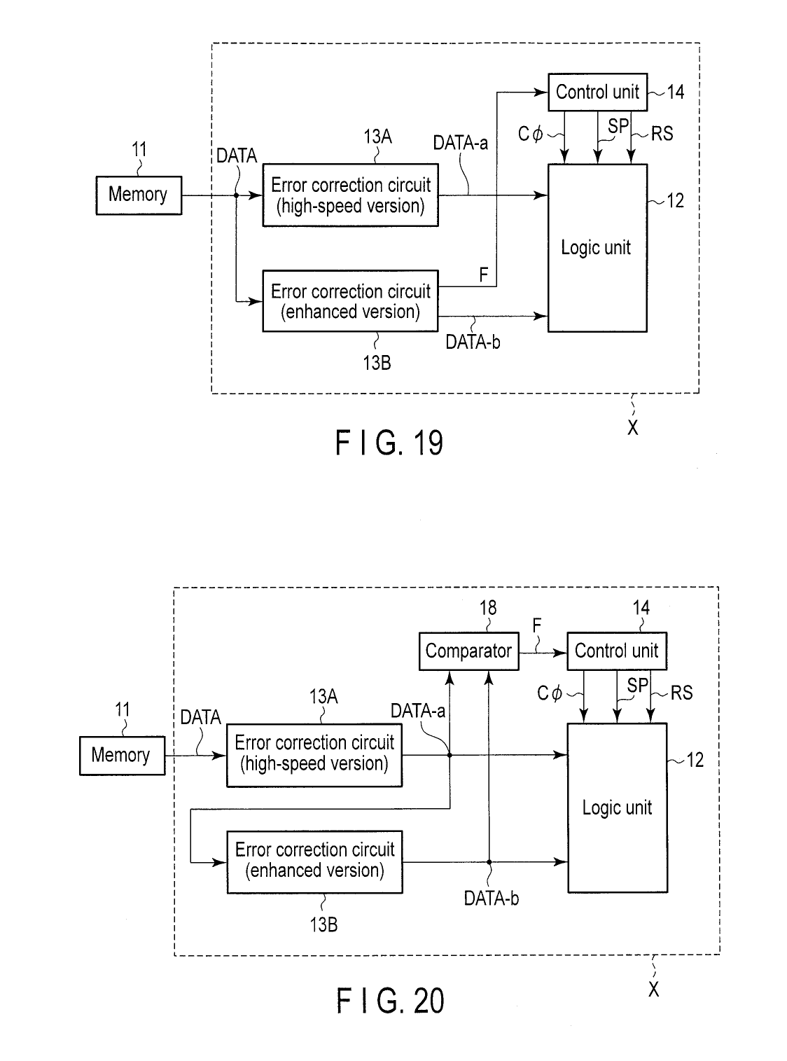

FIG. 19 shows a semiconductor integrated circuit according to the tenth embodiment.

The tenth embodiment is a modification of the ninth embodiment. When compared with the ninth embodiment, the tenth embodiment is characterized by data input into error correction circuit (enhanced version) 13B. The other configuration is the same as shown in FIG. 18 (ninth embodiment) and thus, the same reference numerals are attached to the same elements as those in FIG. 18 to omit a detailed description thereof.

In the present embodiment, first data DATA read from memory 11 is input into error correction circuit (enhanced version) 13B.

FIG. 20 shows a semiconductor integrated circuit according to the eleventh embodiment.

The eleventh embodiment is also a modification of the ninth embodiment. When compared with the ninth embodiment, the eleventh embodiment is characterized in that flag F indicating the presence/absence of an error occurrence in second data DATA-a is generated by comparator 18 that compares second and third data DATA-a, DATA-b. The configuration excluding comparator 18 is the same as shown in FIG. 18 (ninth embodiment) and thus, the same reference numerals are attached to the same elements as those in FIG. 18 to omit a detailed description thereof.

In the present embodiment, second and third data DATA-a, DATA-b are input into comparator 18. Then, comparator 18 outputs flag F indicating the presence/absence of an error occurrence of second data DATA-a by comparing second and third data DATA-a, DATA-b.

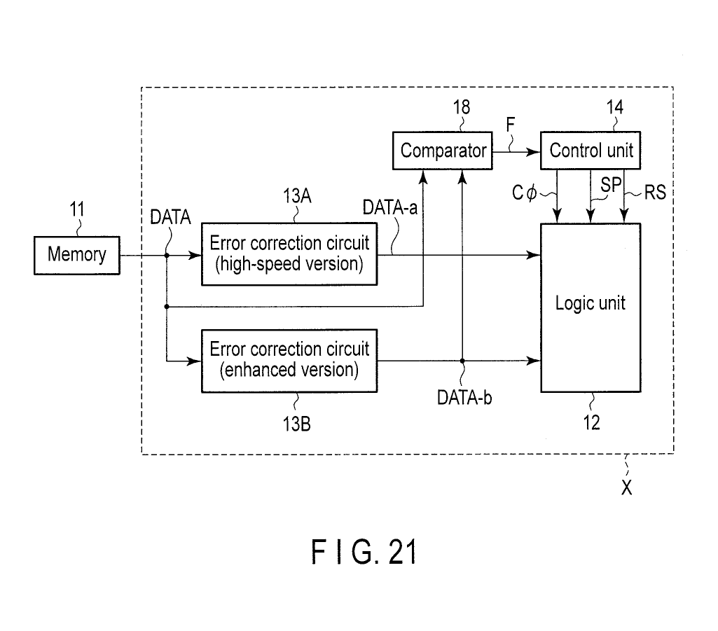

FIG. 21 shows a semiconductor integrated circuit according to the twelfth embodiment.

The twelfth embodiment is a modification of the tenth embodiment. When compared with the tenth embodiment, the twelfth embodiment is characterized in that flag F indicating the presence/absence of an error occurrence in first data DATA is generated by comparator 18 that compares first and third data DATA, DATA-b. The configuration excluding comparator 18 is the same as shown in FIG. 19 (tenth embodiment) and thus, the same reference numerals are attached to the same elements as those in FIG. 19 to omit a detailed description thereof.

In the present embodiment, first and third data DATA, DATA-b are input into comparator 18. Then, comparator 18 outputs flag F indicating the presence/absence of an error occurrence of first data DATA by comparing first and third data DATA, DATA-b.

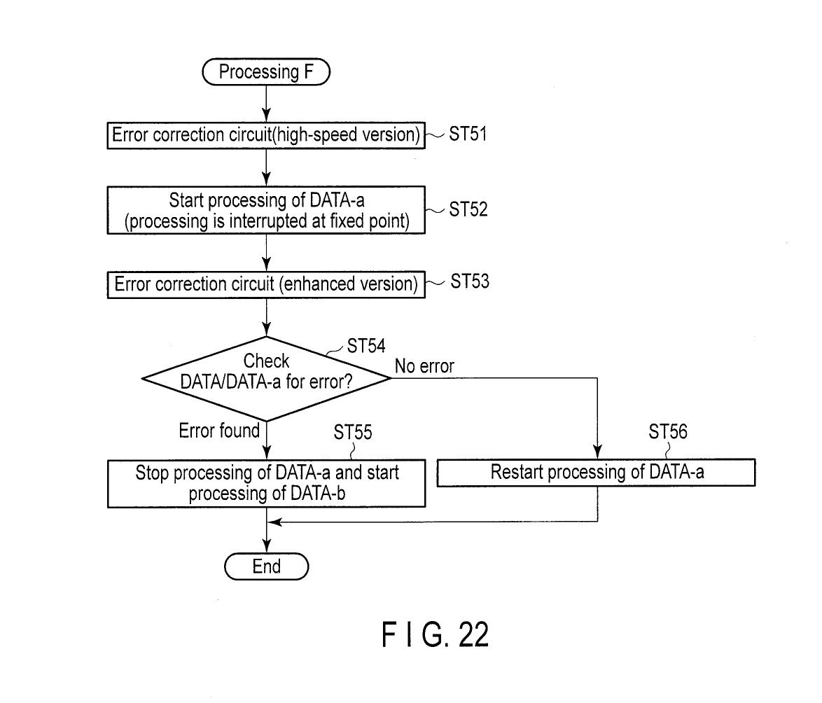

FIG. 22 shows the operation of the circuits in FIGS. 18 to 21.

The operation is controlled by control unit 14 in FIGS. 18 to 21.

First, when first data DATA is read from memory 11, error correction circuit (high-speed version) 13A executes simple error correction processing of first data DATA (step ST51).

Next, logic unit 12 starts data processing (advance processing) of second data DATA-a on which simple error correction processing has been executed. The data processing is interrupted at a fixed point (step ST52).

In parallel with the advance processing, error correction circuit (enhanced version) 13B executes enhanced error correction processing of first data DATA (corresponding to FIGS. 19 and 21) or second data DATA-a (corresponding to FIGS. 18 and 20) (step ST53).

These two steps ST52, ST53 may be interchanged or integrated into one step.

Next, first DATA (corresponding to FIGS. 19 and 21) or second data DATA-a (corresponding to FIGS. 18 and 20) is checked for an error (step ST54).

The check is done based on, for example, flag F output by error correction circuit (enhanced version) 13B or comparator 18. If flag F indicates an error occurrence, logic unit 12 stops data processing of second data DATA-a (resets processing unit 16) and instead, starts data processing of third data DATA-b (step ST55).

If flag F indicates no error occurrence, logic unit 12 restarts data processing of first data DATA-a (step ST56).

Also according to the ninth to twelfth embodiments, as described above, an increase in the data processing time due to the error correction processing can be reduced to a minimum, leading to improved performance of the memory system. Also in the ninth to twelfth embodiments, an effect of reducing the data processing time shown in FIG. 8 can be obtained.

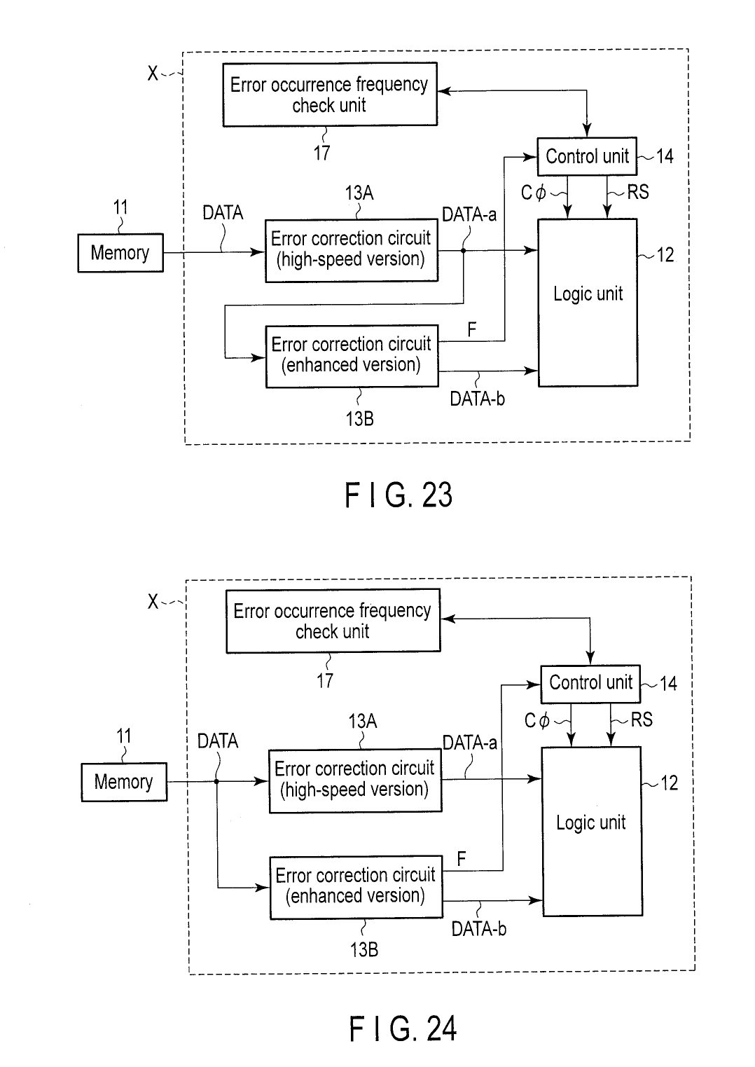

FIGS. 23 to 26 show a semiconductor integrated circuit according to the thirteenth embodiment.

The thirteenth embodiment is a modification of the fifth to eighth embodiments.

When compared with the fifth to eighth embodiments, the thirteenth embodiment is characterized in that error occurrence frequency check unit 17 is further included. The configuration excluding error occurrence frequency check unit 17 is the same as shown in FIGS. 13 to 16 (fifth to eighth embodiments) and thus, the same reference numerals are attached to the same elements as those in FIGS. 13 to 16 to omit a detailed description thereof.

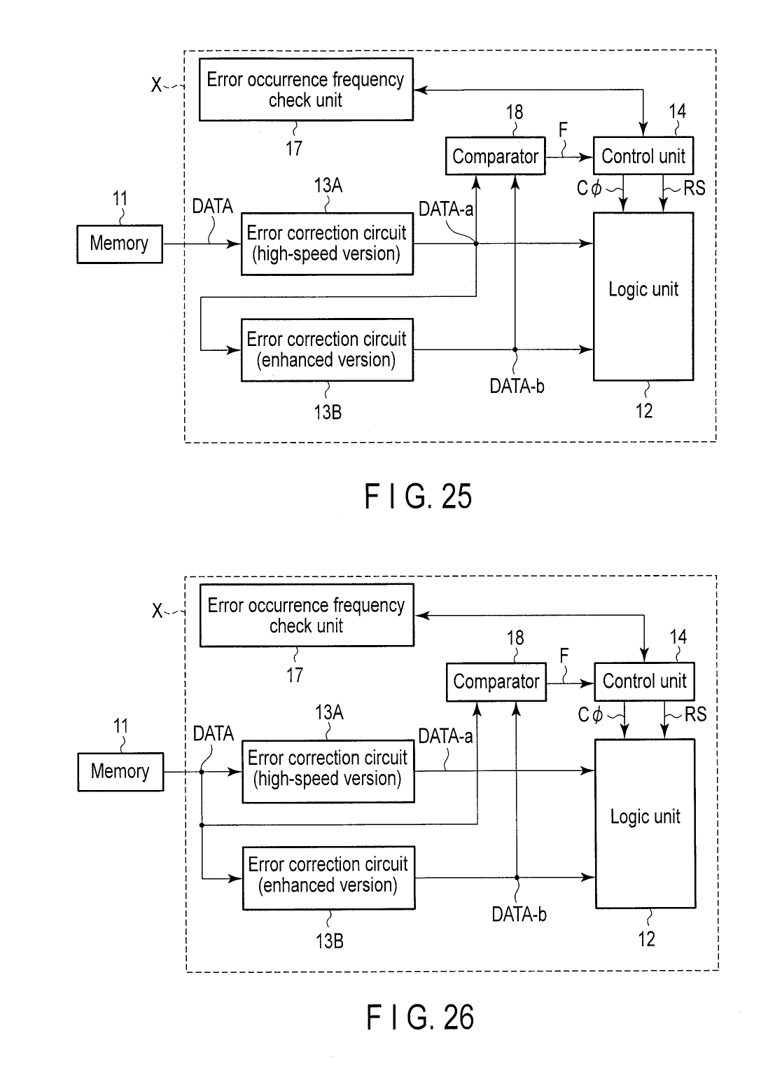

FIG. 23 corresponds to FIG. 13, FIG. 24 corresponds to FIG. 14, FIG. 25 corresponds to FIG. 15, and FIG. 26 corresponds to FIG. 16.

In the present embodiment, error occurrence frequency check unit 17 accumulates and stores the frequency of error occurrence of, for example, first data DATA (corresponding to FIGS. 24 and 26) or second data DATA-a (corresponding to FIGS. 23 and 25). The frequency of error occurrence is accumulated and stored in error occurrence frequency check unit 17 based on, for example, flag F. In this case, flag F contains 1 bit indicating the presence/absence of an error occurrence and bits indicating the frequency of error occurrence (number of error bits).

Then, when the frequency of error occurrence exceeds a predetermined value (permitted value of the number of error bits), control unit 14 causes logic unit 12 to execute data processing on third data DATA-b. For example, control unit 14 continues to output selection signal Cφ to always select third data DATA-b.

In the present embodiment, the configuration inside logic unit 12 is the same as shown in FIG. 2 (first embodiment) and thus, the description here is omitted.

Further, the present embodiment has been described as a modification of the fifth to eighth embodiments, but error occurrence frequency check unit 17 in the present embodiment can also be provided in the ninth to twelfth embodiments.

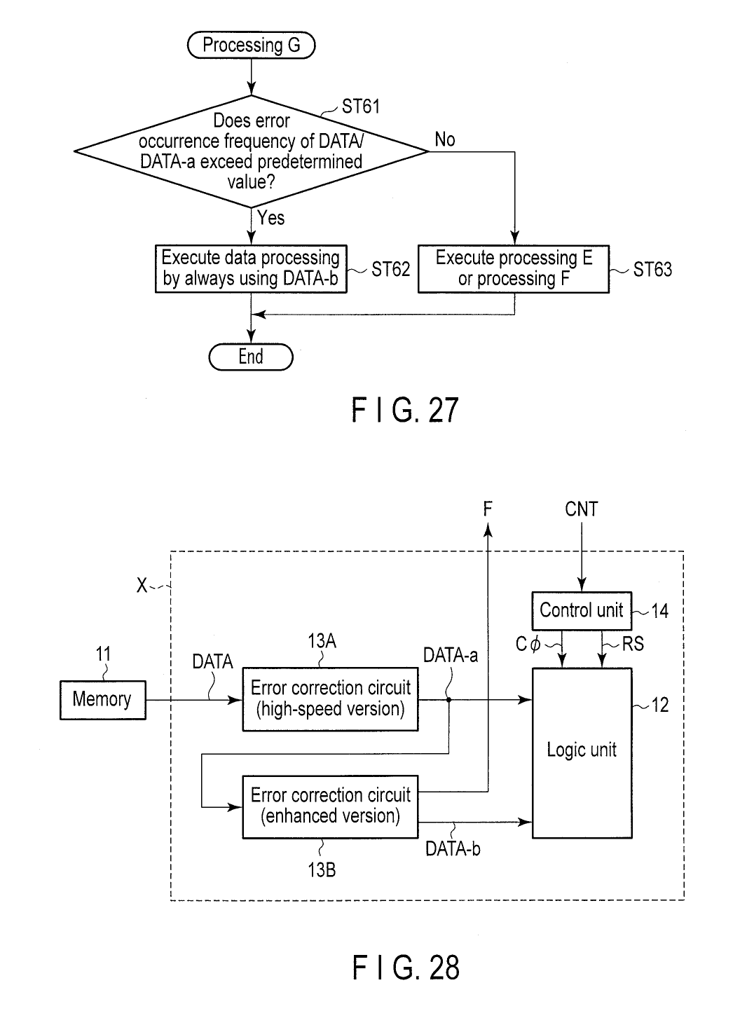

FIG. 27 shows the operation of the circuits in FIGS. 23 to 26.

The operation is controlled by control unit 14 in FIGS. 23 to 26.

First, processing according to the presence/absence of an error in first data DATA (corresponding to FIGS. 24 and 26) or second data DATA-a (corresponding to FIGS. 23 and 25), for example, processing E (FIG. 17) in the fifth to eighth embodiments or processing F (FIG. 22) in the ninth to twelfth embodiments is executed.

Then, whether the frequency of error occurrence of first data DATA (corresponding to FIGS. 24 and 26) or second data DATA-a (corresponding to FIGS. 23 and 25) exceeds the predetermined value is determined (step ST61).

Next, if the frequency of error occurrence exceeds the predetermined value, data processing is executed on third data DATA-b (step ST62). If the frequency of error occurrence does not exceed the predetermined value, processing E (FIG. 17) in the fifth to eighth embodiments or processing F (FIG. 22) in the ninth to twelfth embodiments is continued (step ST63).

FIGS. 28 to 31 show a semiconductor integrated circuit according to the fourteenth embodiment.

The fourteenth embodiment is a modification of the fifth to eighth embodiments.

When compared with the fifth to eighth embodiments, the fourteenth embodiment is characterized in that data (one of second and third data DATA-a, DATA-b) used for data processing by logic unit 12 can be selected based on external control signal CNT. The other configuration is the same as shown in FIGS. 13 to 16 (fifth to eighth embodiments) and thus, the same reference numerals are attached to the same elements as those in FIGS. 13 to 16 to omit a detailed description thereof.

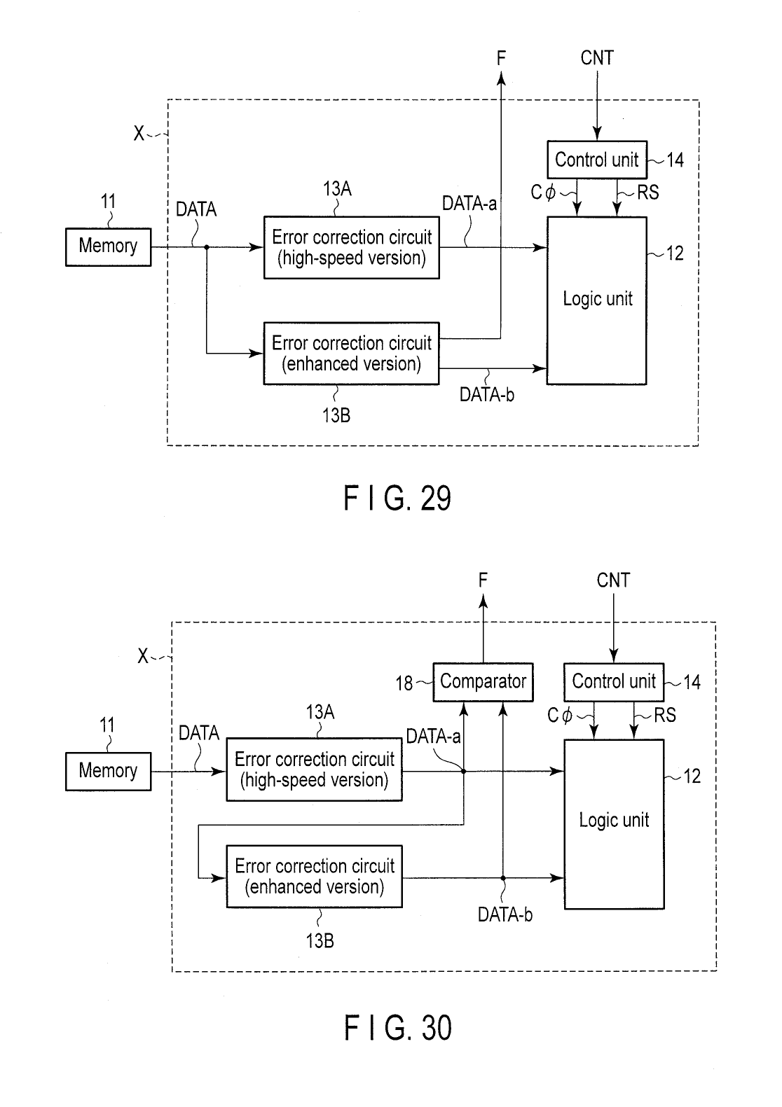

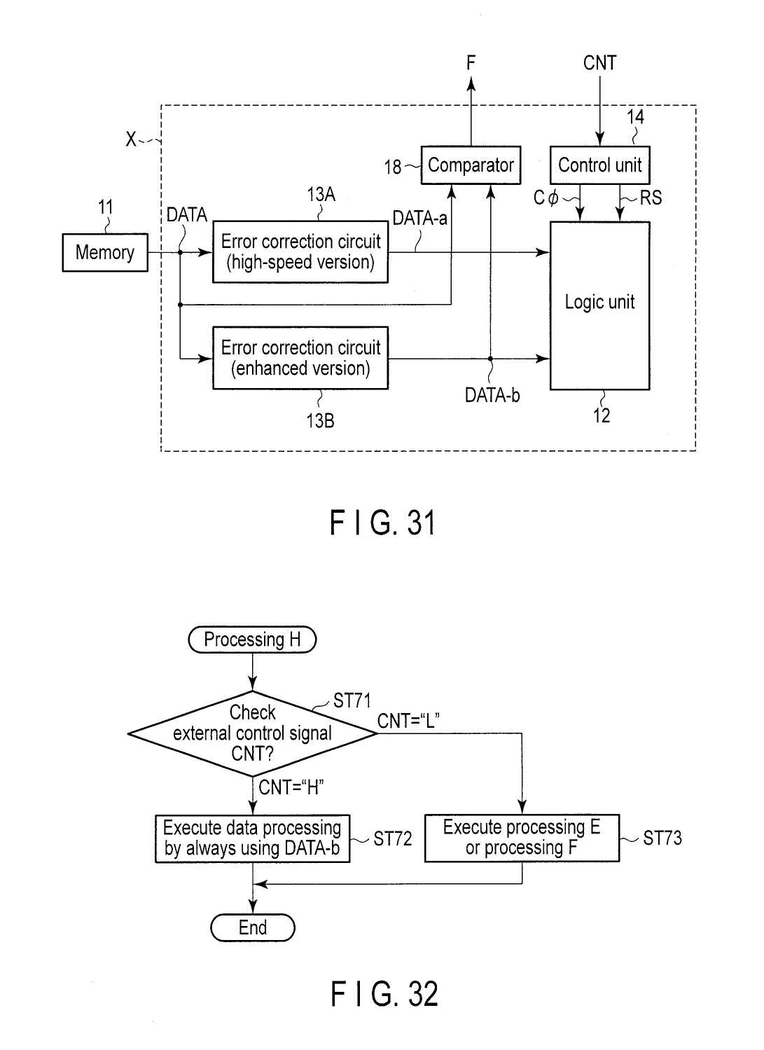

FIG. 28 corresponds to FIG. 13, FIG. 29 corresponds to FIG. 14, FIG. 30 corresponds to FIG. 15, and FIG. 31 corresponds to FIG. 16.

In the present embodiment, when external control signal CNT indicates a predetermined value, logic unit 12 is caused to execute data processing on third data DATA-b. External control signal CNT decides its value based on, for example, flag F from error correction circuit 13. In this case, flag F contains 1 bit indicating the presence/absence of an error occurrence and bits indicating the frequency of error occurrence (number of error bits).

Then, for example, when the frequency of error occurrence exceeds the predetermined value (permitted value of the number of error bits), external control signal CNT indicates a predetermined value to select third data DATA-b. That is, control unit 14 continues to output selection signal Cφ to always select third data DATA-b.

External control signal CNT is generated by a separate host (CPU) from a controller chip X. That is, the host generates external control signal CNT based on, for example, software.

In the present embodiment, the configuration inside logic unit 12 is the same as shown in FIG. 2 (first embodiment) and thus, the description here is omitted. The present embodiment has been described as a modification of the fifth to eighth embodiments, but the present embodiment can also be applied to the ninth to twelfth embodiments.

FIG. 32 shows the operation of the circuits in FIGS. 28 to 31.

The operation is controlled by control unit 14 in FIGS. 28 to 31.

First, processing according to the presence/absence of an error in first data DATA (corresponding to FIGS. 29 and 31) or second data DATA-a (corresponding to FIGS. 28 and 30), for example, processing E (FIG. 17) in the fifth to eighth embodiments or processing F (FIG. 22) in the ninth to twelfth embodiments is executed.

Then, external control signal CNT is checked (step ST71).

Next, if external control signal CNT indicates a predetermined value (for example, “H”), data processing is executed on third data DATA-b (step ST72). If external control signal CNT indicates a value (for example, “L”) other than the predetermined value, processing E (FIG. 17) in the fifth to eighth embodiments or processing F (FIG. 22) in the ninth to twelfth embodiments is executed (step ST73).

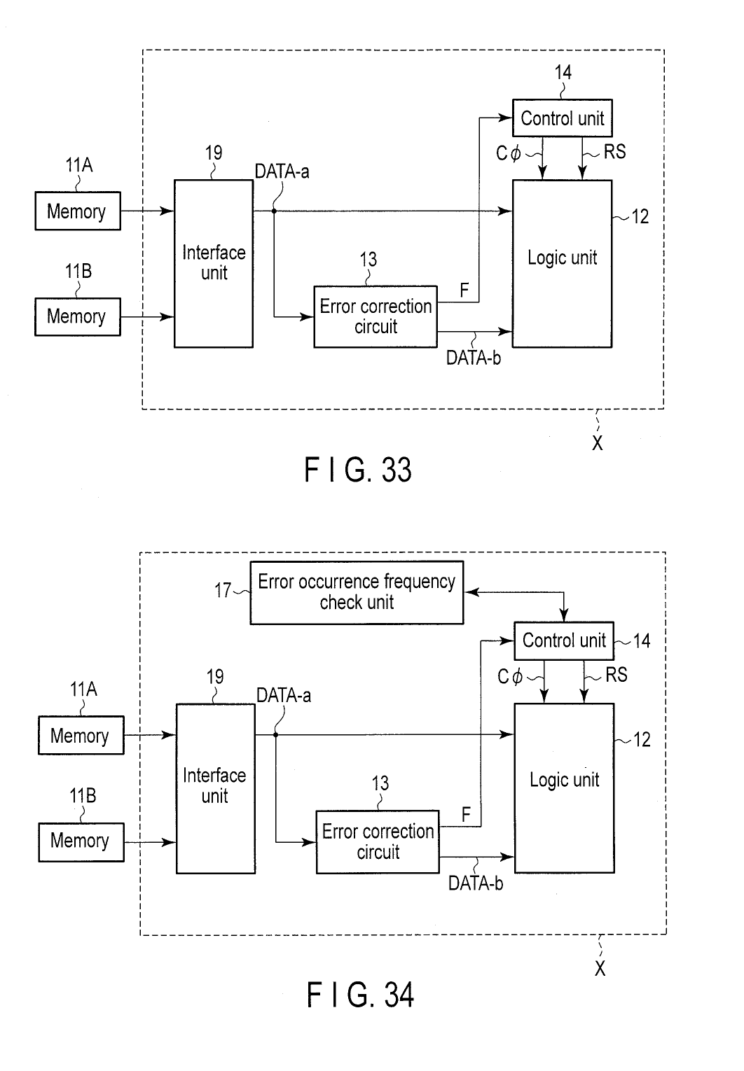

Technology to switch the error correction circuit according to the type/features of memory (FIGS. 33 to 41).

FIGS. 33 to 36 show a semiconductor integrated circuit according to the fifteenth embodiment.

The fifteenth embodiment is a modification of the first, third, fourth, and fifth embodiments.

When compared with the first, third, fourth, and fifth embodiments, the fifteenth embodiment is characterized in that interface unit 19 commonly connecting mutually different first memory 11A and second memory 11B is further included. The configuration excluding interface unit 19 is the same as in the first, third, fourth, and fifth embodiments and thus, a detailed description thereof is omitted.

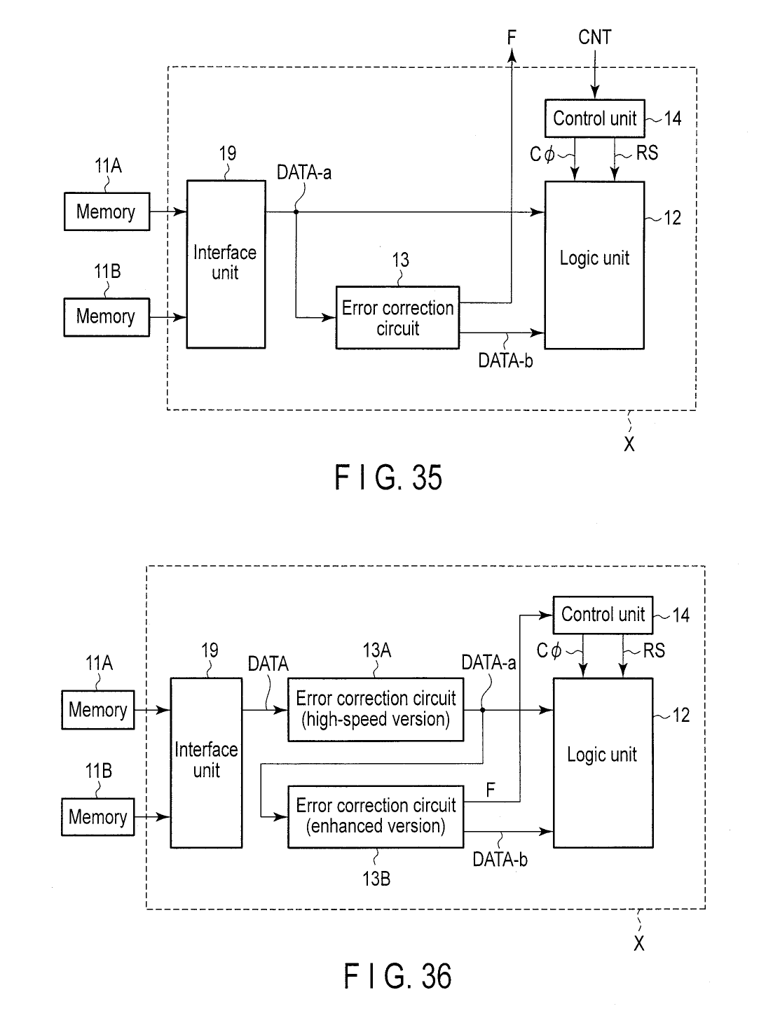

FIG. 33 corresponds to FIG. 1 (first embodiment), FIG. 34 corresponds to FIG. 9 (third embodiment), FIG. 35 corresponds to FIG. 11 (fourth embodiment), and FIG. 36 corresponds to FIG. 13 (fifth embodiment).

The present embodiment can also be applied to the second, sixth, and fourteenth embodiments.

In the present embodiment, first and second memories 11A, 11B may be mutually different types of memories (for example, first memory 11A is a NAND flash memory and second memory 11B is a DRAM) or memories of the same type (for example, the NAND flash memory) having mutually different features (for example, first memory 11A is a binary memory and second memory 11B is a multivalued memory).

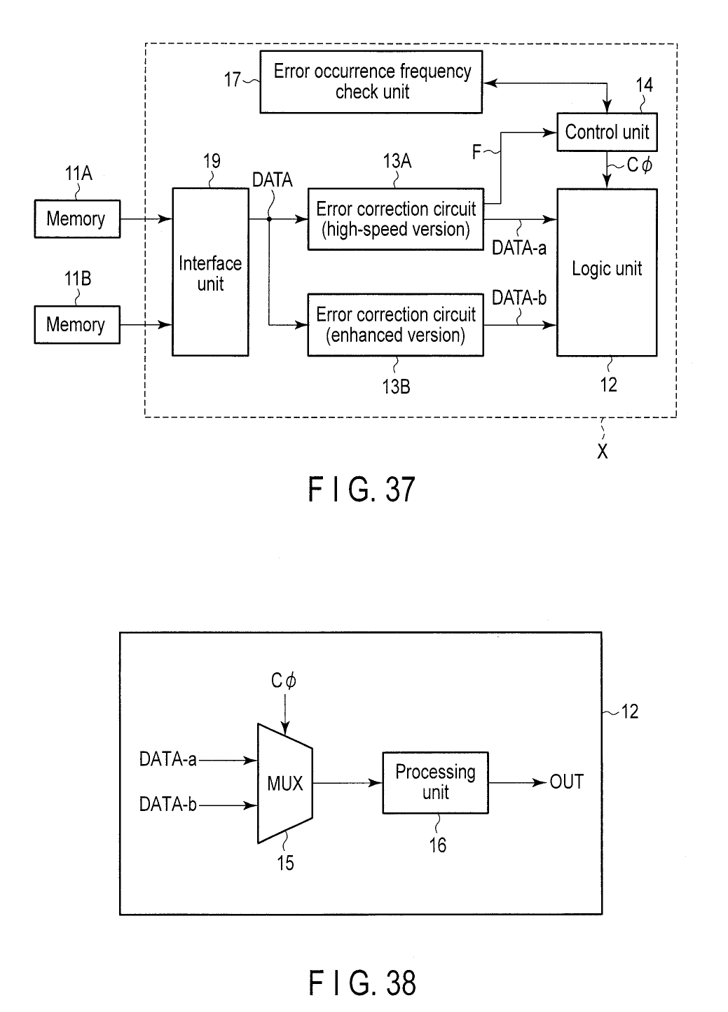

FIG. 37 shows a semiconductor integrated circuit according to the sixteenth embodiment.

Memories 11A, 11B are, for example, a nonvolatile memory such as a NAND flash memory or a volatile memory such as a DRAM. Memories 11A, 11B are commonly connected to interface unit 19.

Error correction circuit (high-speed version) 13A executes error correction processing on first data DATA read from memories 11A, 11B and outputs second data DATA-a on which the error correction processing has been executed. Error correction circuit (enhanced version) 13B executes error correction processing on first data DATA read from memories 11A, 11B and outputs third data DATA-b on which the error correction processing has been executed.

The error correction speed by error correction circuit 13A is faster than the error correction speed by error correction circuit 13B and the error correction function of error correction circuit 13B is more enhanced than the error correction function of error correction circuit 13A. The enhancement here means that, for example, the number of error correctable bits is increased.

Logic unit 12 executes data processing on one of first and second data DATA-a, DATA-b.

When, for example, data DATA is read from memory 11A having a low frequency of error occurrence, control unit 14 uses error-corrected second data DATA-a by error correction circuit (high-speed version) 13A for data processing by logic unit 12. When, for example, data DATA is read from memory 11B having a high frequency of error occurrence, control unit 14 uses error-corrected third data DATA-b by error correction circuit (enhanced version) 13B for data processing by logic unit 12.

Error occurrence frequency check unit 17 stores, for example, the frequency of error occurrence of data DATA read from memory 11A and the frequency of error occurrence of data DATA read from memory 11B based on, for example, flag F output by error correction circuit 13A. The frequency of error occurrence is, for example, the number of error bits occurring in data read from memories 11A, 11B and flag F indicates the presence/absence of error occurrence in error correction circuit 13A or the frequency of error occurrence.

FIG. 38 shows a logic unit in FIG. 37.

Logic unit 12 includes multiplexer 15 that selects one of second and third data DATA-a, DATA-b based on selection signal Cφ and processing unit 16 that executes data processing on one of second and third data DATA-a, DATA-b.

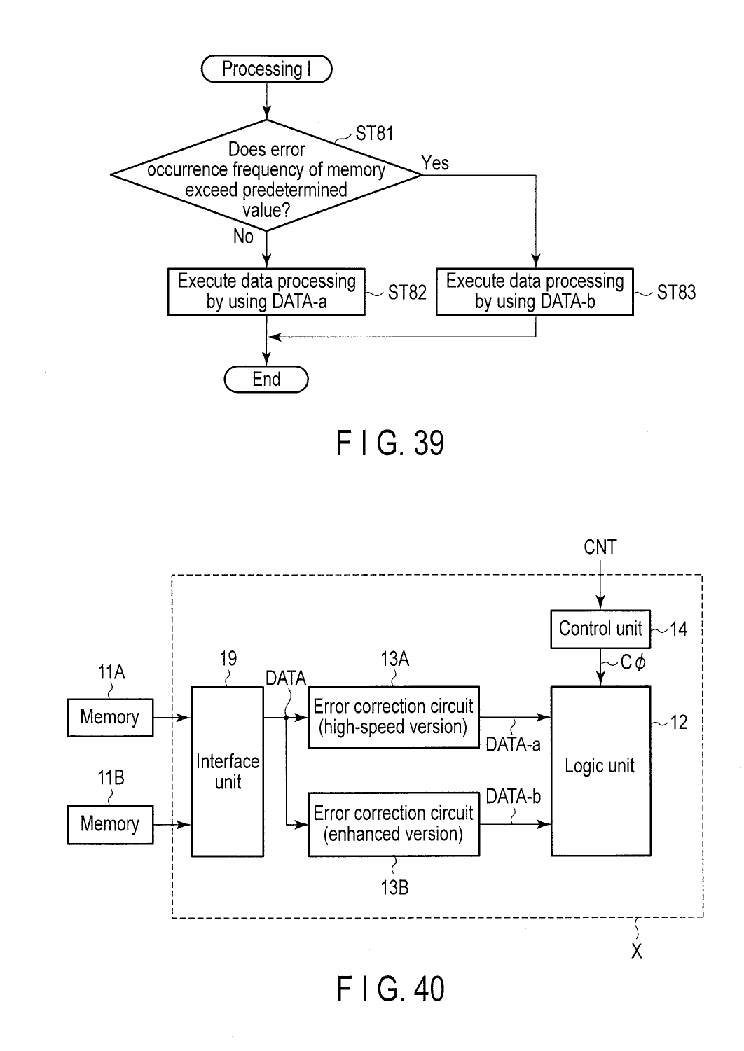

FIG. 39 shows the operation of the circuit in FIG. 37.

The operation is controlled by control unit 14 in FIG. 37.

It is first assumed that the frequency of error occurrence of memory 11B is higher than the frequency of error occurrence of memory 11A.

When reading data DATA from memory 11A, control unit 14 checks the frequency of error occurrence of memory 11A by referring to error occurrence frequency check unit 17. Then, control unit 14 checks whether the frequency of error occurrence of memory 11A exceeds a predetermined value (step ST81).

Because the frequency of error occurrence of memory 11A does not exceed the predetermined value, control unit 14 uses error correction circuit 13A for high-speed error correction processing when data DATA is read from memory 11A and executes data processing on second data DATA-a on which the high-speed error correction processing has been executed (step ST82).

When reading data DATA from memory 11B, control unit 14 checks the frequency of error occurrence of memory 11B by referring to error occurrence frequency check unit 17. Then, control unit 14 checks whether the frequency of error occurrence of memory 11B exceeds a predetermined value (step ST81).

Because the frequency of error occurrence of memory 11B exceeds the predetermined value, control unit 14 uses error correction circuit 13B for enhanced error correction processing when data DATA is read from memory 11B and executes data processing on third data DATA-b on which the enhanced error correction processing has been executed (step ST83).

According to the sixteenth embodiment, as described above, the function of the error correction circuit used for error correction processing can be selected according to the frequency of error occurrence of data read from memories 11A, 11B. Therefore, an increase in the data processing time due to the error correction processing can be reduced to a minimum, leading to improved performance of the memory system.

FIG. 40 shows a semiconductor integrated circuit according to the seventeenth embodiment.

Memories 11A, 11B are, for example, a nonvolatile memory such as a NAND flash memory or a volatile memory such as a DRAM. Memories 11A, 11B are commonly connected to interface unit 19.

Error correction circuit (high-speed version) 13A executes error correction processing on first data DATA read from memories 11A, 11B and outputs second data DATA-a on which the error correction processing has been executed. Error correction circuit (enhanced version) 13B executes error correction processing on first data DATA read from memories 11A, 11B and outputs third data DATA-b on which the error correction processing has been executed.

The error correction speed by error correction circuit 13A is faster than the error correction speed by error correction circuit 13B and the error correction function of error correction circuit 13B is more enhanced than the error correction function of error correction circuit 13A. The enhancement here means that, for example, the number of error correctable bits is increased.

Logic unit 12 executes data processing on one of first and second data DATA-a, DATA-b.

When, for example, data DATA is read from memory 11A having a low frequency of error occurrence, control unit 14 uses error-corrected second data DATA-a by error correction circuit (high-speed version) 13A for data processing by logic unit 12. When, for example, data DATA is read from memory 11B having a high frequency of error occurrence, control unit 14 uses error-corrected third data DATA-b by error correction circuit (enhanced version) 13B for data processing by logic unit 12.

Logic unit 12 in FIG. 40 is the same as that in FIG. 38 and thus, the description here is omitted.

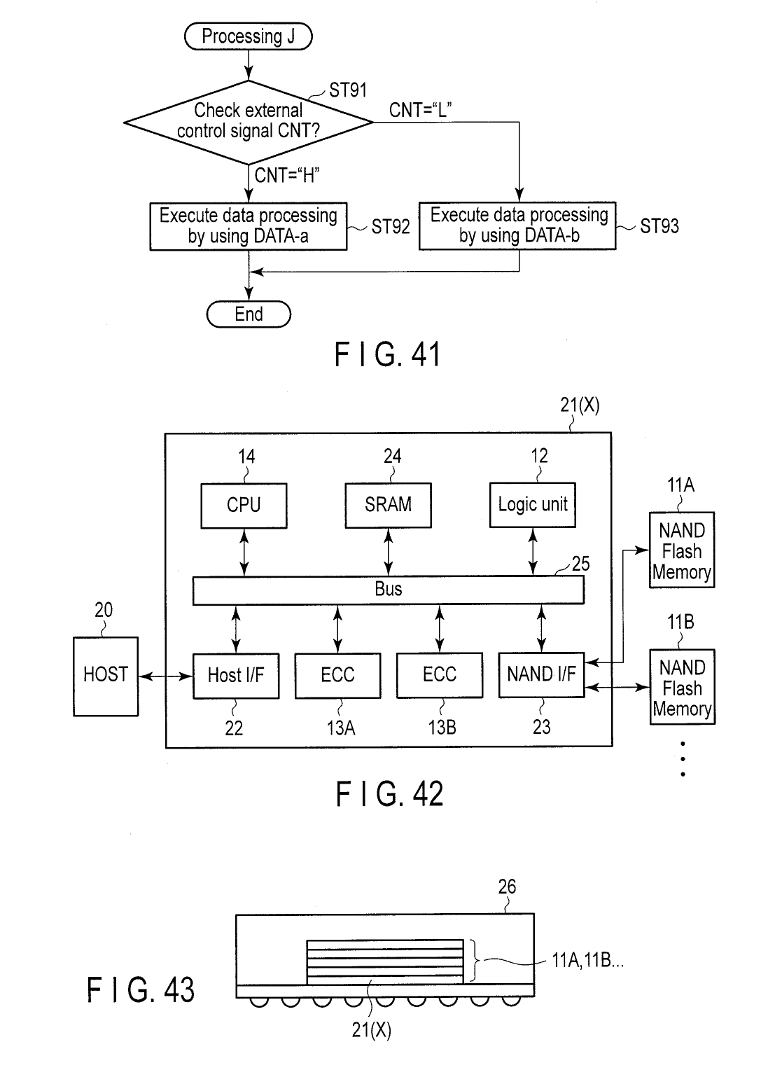

FIG. 41 shows the operation of the circuit in FIG. 40.

The operation is controlled by control unit 14 in FIG. 40.

It is first assumed that the frequency of error occurrence of memory 11B is higher than the frequency of error occurrence of memory 11A.

When reading data DATA from memory 11A, control unit 14 checks external control signal CNT (step ST91).

External control signal CNT is generated based on, for example, the frequency of error occurrence of memory 11A. If external control signal CNT is, for example, “H”, control unit 14 uses error correction circuit 13A for high-speed error correction processing and executes data processing on second data DATA-a on which the high-speed error correction processing has been executed (step ST92).

When reading data DATA from memory 11B, control unit 14 checks external control signal CNT (step ST91).

External control signal CNT is generated based on, for example, the frequency of error occurrence of memory 11B. If external control signal CNT is, for example, “L”, control unit 14 uses error correction circuit 13B for enhanced error correction processing and executes data processing on third data DATA-b on which the enhanced error correction processing has been executed (step ST93).

According to the seventeenth embodiment, as described above, the function of the error correction circuit used for error correction processing can be selected according to the value of external control signal CNT. Therefore, an increase in the data processing time due to the error correction processing can be reduced to a minimum, leading to improved performance of the memory system.

### Others

In the description of the embodiments above, the number of error correction circuits is one or two, but three or more error correction circuits can naturally be used for carrying out the present embodiment.

### (Application Example)

FIG. 42 shows a memory system as an application example.

The present example corresponds to the fifteenth embodiment in FIG. 36, but the memory system can naturally be adopted for other embodiments as an application example.

The system includes host 20, controller 21, and NAND flash memories 11A, 11B, . . . Controller 21 corresponds to semiconductor integrated circuit X according to first to twenty-second embodiments.

Controller 21 includes, for example, logic unit 12, CPU (corresponding to the control unit according to first to twenty-second embodiments) 14, error correction circuits 13A, 13B, host interface 22, NAND interface 23, SRAM (Static random access memory) 24, and bus 25 that connects these elements.

CPU 14 controls the write/read operation of data to/from NAND flash memories 11A, 11B, . . . based on instructions from host 20. NAND flash memories 11A, 11B, . . . may be a binary memory in which two values (1 bit) are stored in one memory cell or a multivalued memory in which three values or more are stored in one memory cell.

Host interface 22 is an interface for host 20 and, for example, USB (Universal serial bus), SATA (Serial Advanced Technology Attachment) or the like can be used. NAND interface 23 is an interface for NAND flash memories 11A, 11B, . . .

SRAM 24 functions as a cache memory for data processing inside controller 21. Error correction circuits 13A, 13B execute error correction processing of data when, for example, data is written/read to/from NAND flash memories 11A, 11B, . . .

FIG. 43 shows an implementation example of the memory system.

For example, the memory system in FIG. 42 can be embedded in one package 26. However, the type of package is not limited to the present example.

Inside one package 26, controller chip 21 (X) and memory chips 11A, 11B, . . . are arranged by being stacked on top of each other. Controller chip 21 corresponds to controller 21 in FIG. 42. Memory chips 11A, 11B, . . . correspond to NAND flash memories 11A, 11B, . . . in FIG. 42.

The number of memory chips 11A, 11B, . . . stacked on controller chip 21 may be one or more.

Controller chip 21 and memory chips 11A, 11B, . . . are connected to each other by wiring technology such as a bonding wire and TSV (Through Silicon Via).

### (Conclusion)

According to the embodiments, an increase in the data processing time due to the error correction processing can be reduced to a minimum.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
an error correction circuit which executes an error correction processing of a first data read from a memory and outputs a second data in which the error correction processing is executed and a flag indicating a presence/absence of an error occurrence of the first data;
a logic unit which executes a data processing of one of the first and second data; and
a control unit which is configured to:
execute the error correction processing of the first data by using the error correction circuit, in parallel with executing the data processing of the first data by using the logic unit,
stop the data processing of the first data in the logic unit and execute the data processing of the second data by using the logic unit, when the flag indicates the error occurrence, and
continues the data processing of the first data in the logic unit when the flag indicates no error occurrence.

2. The circuit of claim 1,
wherein the control unit is configured to:
interrupt the data processing of the first data at a fixed point, after executing the data processing of the first data by using the logic unit; and
restart the data processing of the first data by using the logic unit, when the flag indicates no error occurrence.

3. The circuit of claim 1, further comprising:
an error occurrence frequency check unit which accumulates and stores an error occurrence frequency based on the first data,
wherein the control unit is configured to execute the data processing of the second data by using the logic unit, when the error occurrence frequency exceeds a predetermined value.

4. The circuit of claim 3,
wherein the flag also indicates the error occurrence frequency of the first data and
the error occurrence frequency is accumulated and stored in the error occurrence frequency check unit based on the flag.

5. The circuit of claim 1,
wherein the control unit is configured to execute the data processing of the second data by using the logic unit, when an external control signal indicates a predetermined value.

6. The circuit of claim 5,
wherein the flag also indicates an error occurrence frequency of the first data and
the external control signal indicates the predetermined value when the error occurrence frequency exceeds a predetermined value.

7. A semiconductor integrated circuit comprising:
a first error correction circuit which executes a first error correction processing of a first data and outputs a second data in which the first error correction processing is executed;
a second error correction circuit which executes a second error correction processing of a third data and outputs a fourth data in which the second error correction processing is executed;
a logic unit which executes a data processing of one of the second and fourth data; and
a control unit which is configured to:
execute the error correction processing of the third data by using the second error correction circuit, in parallel with executing the data processing of the second data by using the logic unit,
stop the data processing of the second data in the logic unit and execute the data processing of the fourth data by using the logic unit, when a flag indicating a presence/absence of an error occurrence of the third data indicates the error occurrence of the third data, and
continue the data processing of the second data by using the logic unit, when the flag indicates no error occurrence of the second data.

8. The circuit of claim 7,
wherein the third data is the second data outputted from the first error correction circuit, and the flag is outputted from the second error correction circuit.

9. The circuit of claim 7,
wherein the first and third data is the same data read from a memory, and the flag is outputted from the second error correction circuit.

10. The circuit of claim 7, further comprising:
a comparator which outputs the flag by comparing the second and fourth data;
wherein the third data is the second data outputted from the first error correction circuit.

11. The circuit of claim 7, further comprising:
a comparator which outputs the flag by comparing the first and fourth data;
wherein the first and third data is the same data read from a memory.

12. The circuit of claim 7,
wherein the control unit is configured to:
interrupt the data processing of the second data at a fixed point, after executing the data processing of the second data by using the logic unit; and
restart the data processing of the second data by using the logic unit, when the flag indicates no error occurrence of the second data.

13. The circuit of claim 7, further comprising:
an error occurrence frequency check unit which accumulates and stores an error occurrence frequency based on the second data,
wherein the control unit is configured to execute the data processing of the third data by using the logic unit, when the error occurrence frequency exceeds a predetermined value.

14. The circuit of claim 13,
wherein the flag indicates the error occurrence frequency of the second data, and the error occurrence frequency is cumulatively stored in the error occurrence frequency check unit based on the flag.

15. The circuit of claim 7,
wherein the control unit is executed the logic unit the data processing of the fourth data, when an external control signal indicates a predetermined value.

16. The circuit of claim 15,
wherein the flag indicates the error occurrence frequency of the second data, and the external control signal indicates the predetermined value when the error occurrence frequency is larger than a constant value.

17. A semiconductor integrated circuit comprising:
a first error correction circuit which executes a first error correction processing;
a second error correction circuit which executes a second error correction processing;
a logic unit which executes a data processing; and
a control unit which is configured to:
execute the first error correction processing of a first data based on an control signal and execute the data processing of a third data in which the first error correction processing is executed, when the first data is read from a first memory; and
execute the second error correction processing of the second data based on the control signal and execute the data processing of a fourth data in which the second error correction processing is executed, when the second data is read from a second memory,
wherein the first data has a first error occurrence frequency and the second data has a second error occurrence frequency,
the control signal is generated based on the first and second error occurrence frequencies,
the second error occurrence frequency is higher than the first error occurrence frequency,
an error correction speed of the first error correction circuit is faster than that of the second error correction circuit, and
an error correction function of the second error correction circuit is more enhanced than that of the first error correction circuit.

18. The circuit of claim 17, further comprising
an error occurrence frequency check unit which stores the first and second error occurrence frequencies.

19. The circuit of claim 17,
wherein the control signal is an external control signal.
